(19) United States
(12) Patent Application Publication
(10) Pub. No.: US 2016/0064346 A1
(43) Pub. Date: Mar. 3, 2016

(54) SEMICONDUCTOR DEVICE

(71) Applicant: RENESAS ELECTRONICS CORPORATION, Kawasaki-shi (JP)

(72) Inventor: Tomoo OOTSUKI, Ibaraki (JP)

(73) Assignee: RENESAS ELECTRONICS CORPORATION, Kawasaki-shi (JP)

(21) Appl. No.: 14/735,242

(22) Filed: Jun. 10, 2015

(30) Foreign Application Priority Data
Aug. 26, 2014 (JP) 2014-171764

(51) Int. Cl. H01L 23/00; H01L 23/522

(52) U.S. Cl. CPC H01L 24/05; H01L 23/5226; H01L 23/564; H01L 2224/04042; H01L 2224/0554

(57) ABSTRACT

This invention provides a semiconductor device with improved reliability. A pad includes a slit portion formed so as to pass through the pad, and also includes a bonding portion positioned inside the slit portion in plan view, and an edge portion positioned outside the slit portion in plan view. In plan view, a via encloses the slit portion and is in contact with the bonding portion of the pad and the edge portion of the pad.

### CROSS-REFERENCE TO RELATED APPLICATIONS

The disclosure of Japanese Patent Application No. 2014-171764 filed on Aug. 26, 2014 including the specification, drawings and abstract is incorporated herein by reference in its entirety.

### BACKGROUND

This invention relates to semiconductor devices, and, for example, to a technique effectively applicable to a semiconductor device with a via coupled to a pad.

Japanese Unexamined Patent Application Publication No. Hei 9(1997)-36166 discloses a technique of forming a slit in a bonding pad.

### SUMMARY

The technique of forming a slit in a pad, for example, can inhibit pad corrosion caused by stress that is applied to the pad during wire bonding because the stress can be reduced by a molding compound embedded in the slit after the wire bonding.

However, since the slit is formed so as to pass through the pad, moisture may enter inside the semiconductor chip through the slit. The technique of forming a slit in a pad, therefore, is required to prevent moisture from entering inside the semiconductor chip in order to improve the reliability of the semiconductor device.

The other problems and novel features of the present invention will become apparent from the following description in the present specification and the accompanying drawings.

In a semiconductor device according to an embodiment, a pad includes a slit portion passing through the pad, a bonding portion positioned inside the slit portion in plan view, and an edge portion positioned outside the slit portion in plan view. In plan view, a via encloses the slit portion and is in contact with the bonding portion of the pad and the edge portion of the pad.

According to the embodiment, the semiconductor device can have improved reliability.

### BRIEF DESCRIPTION OF THE DRAWINGS

FIG. 1 is a plan view of a QFP-packaged semiconductor device viewed from above.

FIG. 2 is a cross-sectional view taken along line A-A in FIG. 1.

FIG. 3 shows a layout configuration of a semiconductor chip. FIG. 4 is a plan view schematically showing a pad of related art.

FIG. 5 is a cross-sectional view taken along line A-A in FIG. 4.

FIG. 6 is a plan view schematically showing a pad according to the first embodiment.

FIG. 7 is a cross-sectional view taken along line A-A in FIG. 6.

FIG. 8 is a cross-sectional view to describe a manufacturing process for a semiconductor device according to the first embodiment.

FIG. 9 is a cross-sectional view to describe a semiconductor device manufacturing process subsequent to FIG. 8.

FIG. 10 is a cross-sectional view to describe a semiconductor device manufacturing process subsequent to FIG. 9.

FIG. 11 is a cross-sectional view to describe a semiconductor device manufacturing process subsequent to FIG. 10.

FIG. 12 is a cross-sectional view to describe a semiconductor device manufacturing process subsequent to FIG. 11.

FIG. 13 is a cross-sectional view to describe a semiconductor device manufacturing process subsequent to FIG. 12.

FIG. 14 is a cross-sectional view to describe a semiconductor device manufacturing process subsequent to FIG. 13.

FIG. 15 is a cross-sectional view to describe a semiconductor device manufacturing process subsequent to FIG. 14.

FIG. 16 is a cross-sectional view to describe a semiconductor device manufacturing process subsequent to FIG. 15.

FIG. 17 is a plan view schematically showing a pad according to the second embodiment.

FIG. 18 is a cross-sectional view taken along line A-A in FIG. 17.

FIG. 19 is a plan view schematically showing a pad according to the third embodiment.

FIG. 20 is a cross-sectional view showing an exemplary configuration of a semiconductor device according to the fourth embodiment.

FIG. 21 is a cross-sectional view to describe a manufacturing process for the semiconductor device according to the fourth embodiment.

FIG. 22 is a cross-sectional view to describe a semiconductor device manufacturing process subsequent to FIG. 21.

FIG. 23 is a cross-sectional view to describe a semiconductor device manufacturing process subsequent to FIG. 22.

FIG. 24 is a cross-sectional view to describe a semiconductor device manufacturing process subsequent to FIG. 23.

FIG. 25 is a cross-sectional view to describe a semiconductor device manufacturing process subsequent to FIG. 24.

FIG. 26 is a cross-sectional view to describe a semiconductor device manufacturing process subsequent to FIG. 25.

FIG. 27 is a cross-sectional view to describe a semiconductor device manufacturing process subsequent to FIG. 26.

FIG. 28 is a cross-sectional view to describe a semiconductor device manufacturing process subsequent to FIG. 27.

FIG. 29 is a cross-sectional view to describe a semiconductor device manufacturing process subsequent to FIG. 28.

FIG. 30 is a plan view showing a plane shape of a pad according to the fifth embodiment.

FIG. 31 is a plan view showing a plane shape of a pad according to the fifth embodiment.

### DETAILED DESCRIPTION

In the following embodiments, if necessary for convenience, an embodiment will be divided into a plurality of sections or embodiments in the description; however, excepting the case that is particularly demonstrated, these are not independent of each other, but are in a relationship in which one is a variation(s) of part or all of the other, a detailed description, a supplementary description, or the like.

Also, in the following embodiments, when the number of elements and the like (including the number, the numeric value, the quantity, the range, and the like) are cited, excepting the case that is particularly demonstrated, the case in which the embodiment is clearly limited in principle to the particular number, and the like, the embodiment is not limited to the particular number, but the number maybe more than or less than the particular number.

Additionally, in the following embodiments, the constituent components (including component steps and the like) are not necessarily required, excepting the case that is particularly demonstrated, the case in which the components are clearly required in principle, and the like.

Similarly, in the following embodiments, when contours, positional relationships, and the like of the constituent components are cited, excepting the case that is particularly demonstrated, the case in which the components are obviously inappropriate in principle, and the like, it is assumed that those substantially approximate to or analogous to the contours or the like are included. This is also applied to the numeric value and the range described above.

Moreover, in all the drawings to describe the embodiments, the same reference numerals are assigned to the same members in principle, and explanations thereof will not be repeated. Note that hatching may be sometimes used even in a plan view so as to make the drawings easy to see.

### First Embodiment

### <Exemplary Configuration of Semiconductor Device (QFP Package)>

There are various types of semiconductor device package structures, such as ball grid array (BGA) packages and quad flat packages (QFP). The technical idea of the first embodiment can be applied to these packages. In the following, the configuration of a semiconductor device of a QFP package type will be described as an example.

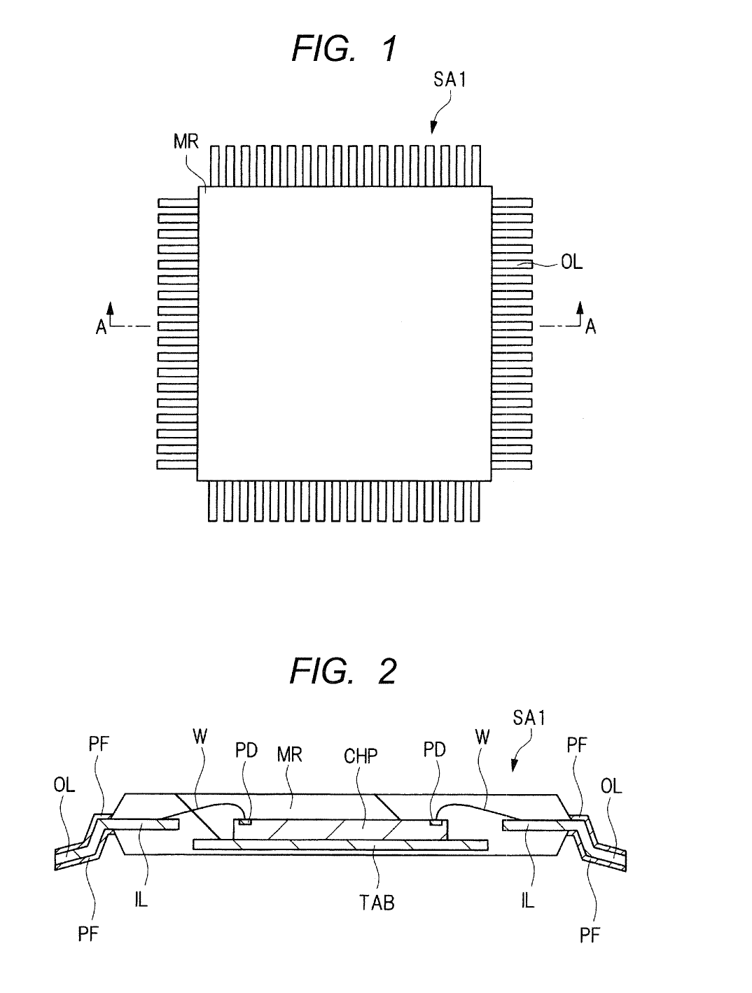

FIG. 1 is a plan view of a QFP-packaged semiconductor device SA1 viewed from above. As shown in FIG. 1, the semiconductor device SA1 is rectangular and has an upper surface covered with resin (sealing member) MR. From the four sides which define the contour of the resin MR, outer leads OL project outwardly.

A description about the internal structure of the semiconductor device SA1 will follow. FIG. 2 is a cross-sectional view taken along line A-A in FIG. 1. As shown in FIG. 2, the back side of a chip mount portion TAB is covered with the resin MR. On the other hand, a semiconductor chip CHP is mounted over the upper side of the chip mount portion TAB that is separated from inner leads IL (lead terminals). Pads PD are formed in the main surface of the semiconductor chip CHP. The pads PD formed in the semiconductor chip CHP are electrically coupled to the inner leads IL with wires W. The semiconductor chip CHP, wire W, and inner leads IL are covered with the resin MR, while the outer leads OL (lead terminals), which are integrally formed with the inner leads IL, stick out from the resin MR. Each of the outer leads OL sticking out from the resin MR is formed in the shape of a gull wing and has a plating film PF formed over the outer surface thereof.

The chip mount portion TAB, inner leads IL, and outer leads OL are made of, for example, alloy 42, which is an alloy of a copper material, iron, and nickel, or the like, while the wires W are made of, for example, a gold wire. The semiconductor chip CHP is made of, for example, silicon or a compound semiconductor (e.g., GaAs), and has a plurality of semiconductor elements, such as a MOSFET, formed therein. Above the semiconductor elements formed are multilevel interconnects through interlayer insulating films. The pads PD are formed in the uppermost layer of the multilevel interconnects to couple with the multilevel interconnects. The semiconductor elements formed in the semiconductor chip CHP are electrically coupled to the pads PD via the multilevel interconnects. In other words, an integrated circuit is made up with the semiconductor elements and multilevel interconnects formed in the semiconductor chip CHP, and terminals coupling the integrated circuit to the outside of the semiconductor chip CHP are the pads PD. The pads PD are coupled to the inner leads IL with the wires W and resultantly coupled to the outer leads OL which are integrally formed with the inner leads IL. It is appreciated from the above description that the integrated circuit formed in the semiconductor chip CHP is electrically coupled to the outside of the semiconductor device SA1 along a path from the pad PD through the wires W, the inner leads IL, and the outer leads OL to an external coupling device. In other words, the integrated circuit formed in the semiconductor chip CHP can be controlled by inputting electrical signals from the outer leads OL formed on the semiconductor device SA1. Conversely, output signals can be taken out from the integrated circuit through the outer leads OL to the outside.

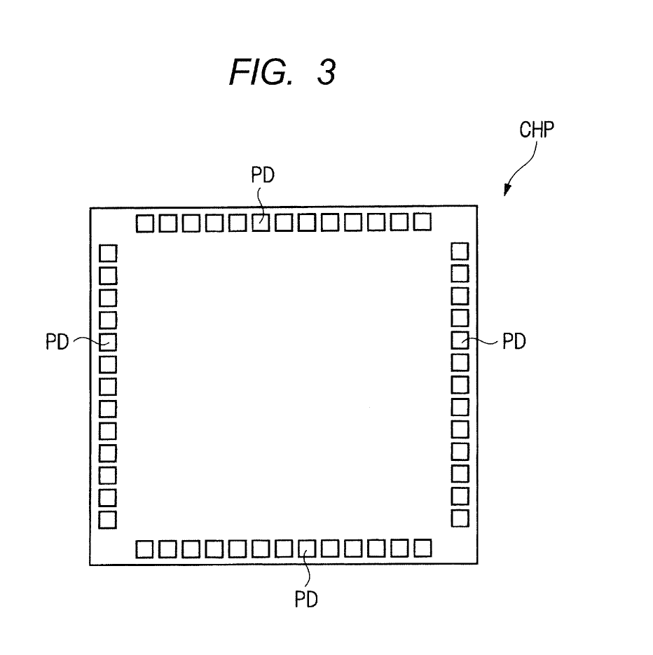

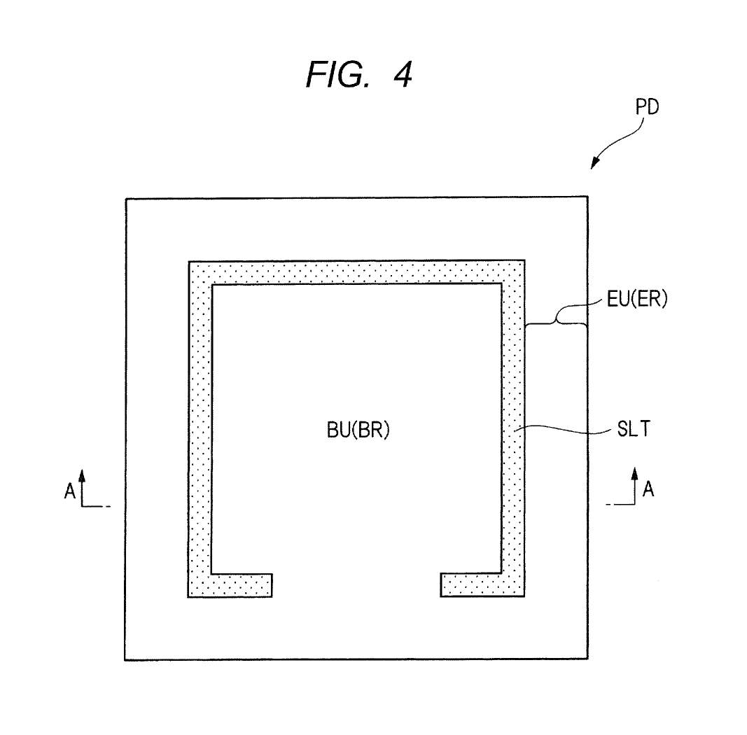

FIG. 3 illustrates a layout configuration of the semiconductor chip CHP. In FIG. 3, the semiconductor chip CHP is, for example, rectangular, and a plurality of pads PD are disposed along the sides of the semiconductor chip CHP. Although it is not shown in FIG. 3, the most part of the upper surface of each pad PD is exposed from an opening formed in a surface protective film, while the edges of the pad PD are covered with the surface protective film.

A description about a pad structure of related art will be given at first, and possible improvements in the related art will be presented below.

### <Pad Structure of Related Art>

FIG. 4 is a plan view schematically showing a pad PD of related art. In FIG. 4, the pad PD of the related art is rectangular and has a slit portion SLT formed therein. An area outside this slit portion SLT is an edge portion EU of the pad PD. In this specification, the region where the edge portion EU is formed is referred to as an edge region ER. On the other hand, an area inside the slit portion SLT is a bonding portion BU of the pad PD, and a wire is coupled to this bonding portion BU. In this specification, the region where the bonding portion BU is formed is referred to as a bonding region BR.

In FIG. 4, part of a sealing member MR (see FIG. 2), which is used to seal the semiconductor device, fills up the slit portion SLT in the pad PD of the related art. According to the related art, even if stress induced by wire bonding is applied to the pad PD, the sealing member filled in the slit portion SLT after the wire bonding processing can relieve the stress on the pad PD, thereby inhibiting stress-induced corrosion in the pad PD.

As shown in FIG. 4, the pad PD according to the related art is a rectangular pad having a slit portion SLT that is formed along the sides thereof, but is not formed at a part of one of the sides in order to electrically couple the bonding portion BU and edge portion EU of the pad PD. The part where the slit portion SLT is not formed is referred to as a slit-unformed region.

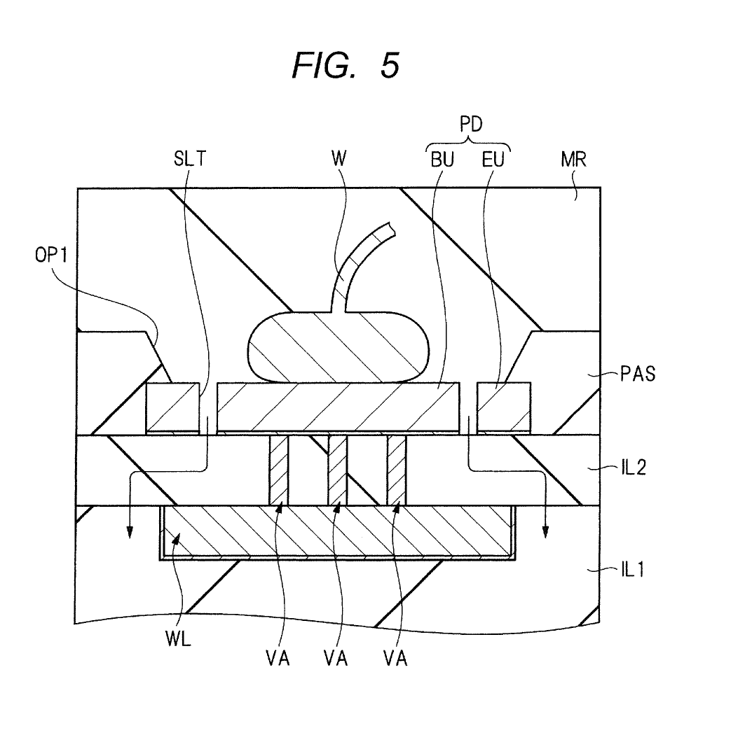

FIG. 5 is a cross-sectional view taken along line A-A in FIG. 4. As shown in FIG. 5, a wiring WL, which is, for example, a copper line formed by a damascene method, is formed in an interlayer insulating film IL1, and an interlayer insulating film IL2 is formed over the interlayer insulating film IL1 including the wiring WL. In the interlayer insulating film IL2, a plurality of vias VA are formed so as to pass through the interlayer insulating film IL2 to reach the wiring WL. Over the interlayer insulating film IL2 including the vias VA, a pad PD is formed having a bonding portion BU and an edge portion EU. Specifically, a slit portion SLT is formed in the pad PD of the related art so as to pass through the pad PD, and the slit portion SLT distinguishes between the bonding portion BU and edge portion EU.

In the related art, as shown in FIG. 5, the bonding portion BU of the pad PD is coupled to the vias VA. In other words, the bonding portion BU of the pad PD of the related art is coupled to the wiring WL disposed in the layer below the pad PD through the vias VA. A surface protective film PAS is formed so as to cover the pad PD, and then an opening OP1 is formed in the surface protective film PAS so as to expose a part of the pad PD. More specifically, the opening OP1 is formed so as to expose the entire bonding portion BU and a part of the edge portion EU of the pad PD. In this situation, a wire W is coupled to the bonding portion BU of the pad PD exposed from the opening OP1, and is covered with a sealing member MR. The sealing member MR is formed over the surface protective film PAS including the opening OP1, and the sealing material of the sealing member MR fills the slit portion SLT of the pad PD exposed from the opening OP1.

The pad structure of the related art is established as described above. The inventors of the present invention have reviewed the pad structure and revealed that the pad structure of the related art has room for improvement from the view point of preventing moisture from entering inside the semiconductor chip. The following is a description about the pad structure to be improved in the related art.

### <Pad Structure to be Improved in Related Art>

As shown in FIG. 5, the pad PD in the related art has a slit portion SLT formed so as to pass through the pad PD. Therefore, it is appreciated, as indicated by arrows in FIG. 5, that there are formed paths through which moisture enters inside the semiconductor chip through the slit portion SLT. More specifically, the slit portion SLT passing through the pad PD is provided to relieve the stress applied to the pad PD due to wire bonding in the related art; however, this slit portion SLT makes it easy for moisture to enter inside the semiconductor chip. The entry of moisture inside the semiconductor chip impairs the reliability of the semiconductor device, typified by operation failure. This proves that the related art has room to be improved to prevent moisture from entering inside the semiconductor chip from the view point of improving the semiconductor device reliability. The first embodiment has been made to ameliorate the impairment residing in the related art. A description below will be made about the technical idea of the first embodiment that ameliorates the related art.

### Pad Structure and Via Structure of First Embodiment

FIG. 6 is a plan view schematically showing a pad PD according to the first embodiment. In FIG. 6, the pad PD according to the first embodiment is rectangular and has a slit portion SLT formed along the sides of the pad PD. The slit portion SLT is filled with a sealing member for the semiconductor device. In plan view, the region outside the slit portion SLT is an edge region ER, and an edge portion EU of the pad PD is formed in the edge region ER. On the other hand, the region inside the slit portion SLT is a bonding region BR, and a bonding portion BU of the pad PD is formed in the bonding region BR.

In FIG. 6, a via VA1, which is indicated by a dashed line in FIG. 6, is formed in a lower layer of the pad PD. This via VA1 is formed so as to enclose the bonding portion BU and slit portion SLT of the pad PD in plan view and is in contact with the edge portion EU of the pad PD.

In addition, as shown in FIG. 6, a surface protective film PAS is formed so as to cover a surface area of the pad PD. This surface protective film PAS has an opening OP1 that exposes a part of the surface area of the pad PD. In plan view, the bonding portion BU and slit portion SLT of the pad PD are positioned within the opening OP1.

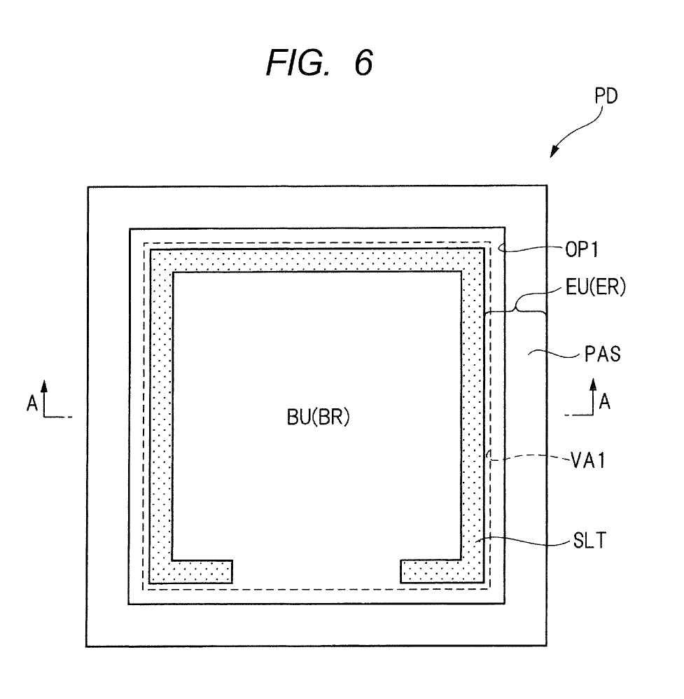

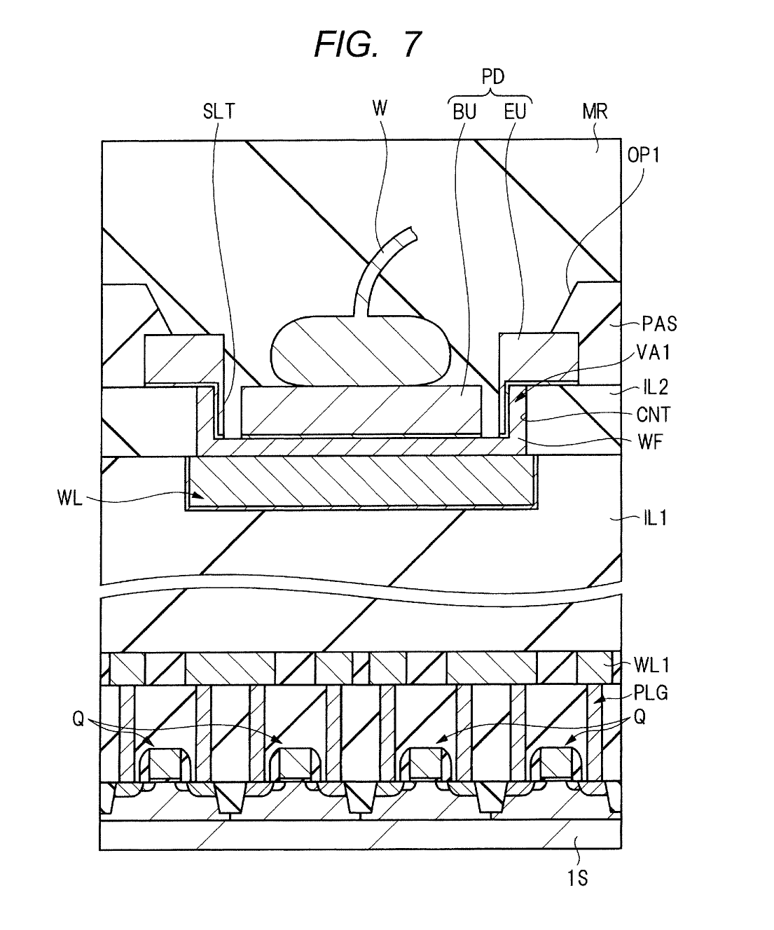

FIG. 7 is a cross-sectional view taken along line A-A in FIG. 6. As shown in FIG. 7, for example, a plurality of field-effect transistors Q configuring an integrated circuit are formed over a main surface of a semiconductor substrate 1S which is made of silicon. An interlayer insulating film is formed so as to cover the field-effect transistors Q, and plugs PLG that are electrically coupled to the field-effect transistors Q are formed so as to pass through the interlayer insulating film. Over the interlayer insulating film with the plugs PLG formed therein, for example, formed are wirings WL1, which contain copper as a main component, by a damascene method. The wirings WL1 are electrically coupled to the field-effect transistors Q via the plugs PLG. Although it is not illustrated in FIG. 7, multilevel interconnects are formed over the wirings WL 1, and an interlayer insulating film IL1 is formed so as to cover the multilevel interconnects.

The term “main component” used herein denotes a material component contained the most in the constituent materials making up the structural component. For example, “a material containing copper as a main component” denotes that the material of the structural component contains copper at the highest rate. The reason for using the term “main component” in this specification is to express, for example, that the structural component is basically made of copper, but the possibility of including impurities in addition to the copper cannot be eliminated.

As shown in FIG. 7, a wiring WL, which contains copper as a main component, is formed in the interlayer insulating film IL1 by, for example, a damascene method, and an interlayer insulating film IL2 is formed over the interlayer insulating film IL1 including the wiring WL. A coupling hole CNT is formed in this interlayer insulating film IL2, and a tungsten film WF, which contains tungsten (W) as a main component, is formed over inner walls of the coupling hole CNT. In the first embodiment, the tungsten film WF formed over the inner walls of the coupling hole CNT forms the via VA1. The via VA1 is also formed over the wiring WL in the interlayer insulating film IL1 so that the via VA1 is electrically coupled to the wiring WL. The bonding portion BU of the pad PD is formed so as to be enclosed by the via VA1, while the edge portion EU of the pad PD is formed across from side walls of the via VA1 up to the interlayer insulating film IL2. Specifically, the via VA1 and bonding portion BU of the pad PD are directly and electrically coupled to each other, as well as the via VA1 and edge portion EU of the pad PD are directly and electrically coupled to each other. It is understood from the above description that the pad PD is electrically coupled to the wiring WL through the via VA1.

The pad PD has a slit portion SLT passing therethrough and is separated into the bonding portion BU and edge portion EU by the slit portion SLT. At the bottom of the slit portion SLT formed in the pad PD, a surface of the via VA1 is exposed. In the first embodiment, as shown in FIG. 7, the bonding portion BU of the pad PD is enclosed in the via VA1 and the edge portion EU of the pad PD is formed across from the side walls of the via VA1 up to the interlayer insulating film IL2, thereby making a difference in level between the bonding portion BU and the edge portion EU of the pad PD. Specifically, the pad PD according to the first embodiment has the bonding portion BU whose upper surface is at a lower level than the upper surface of the edge portion EU in association with the positional relationship in which the bonding portion BU of the pad PD is enclosed by the via VA1, but the edge portion EU of the pad PD extends from the via VA1. In other words, in the pad PD according to the first embodiment, the upper surface of the edge portion EU of the pad PD is at a higher level than the upper surface of the bonding portion BU of the pad PD.

Then, as shown in FIG. 7, a surface protective film PAS is formed so as to cover the pad PD, and an opening OP1 is formed in the surface protective film PAS so as to expose a part of the upper surface of the pad PD. Specifically, the entire bonding portion BU of the pad PD and a part of the edge portion EU of the pad PD are exposed from the opening OP1 formed in the surface protective film PAS. In short, as shown in FIG. 7, the opening OP1 is formed in the surface protective film PAS so that its end portion is located at the edge portion EU of the pad PD.

A wire W, which is made of, for example, a gold wire, is coupled to the bonding portion BU, and a sealing member MR, which is made of, for example, resin (sealing material), is formed so as to cover the wire W and the interior part of the opening OP1 as well as over the surface protective film PAS. Thus, in the first embodiment, the slit portion SLT of the pad PD, which is exposed from the opening OP1, is filled up with the resin (sealing material). Accordingly, as with the case of the related art, even if stress caused by wire bonding is applied to the pad PD in the first embodiment, the sealing material that is embedded in the slit portion SLT after the wire bonding process can relieve the stress, thereby gaining the advantage that stress-induced corrosion of the pad PD can be inhibited.

Furthermore, the pad structure and via structure in the first embodiment shown in FIG. 7 allow both formation of the slit portion SLT in the pad PD and inhibition of moisture entry into the semiconductor chip. Specifically, according to the pad structure and via structure of the first embodiment, the stress applied to the pad PD due to wire bonding can be relieved by forming the slit portion SLT in the pad PD, while the potential for moisture entry into the semiconductor chip due to the slit portion SLT can be greatly inhibited. The features of the first embodiment having such technical significance will be described below.

### Features of First Embodiment

The features of the first embodiment reside in that on the precondition that the pad PD has a bonding portion BU inside the slit portion SLT and an edge portion EU outside the slit portion SLT as shown in FIG. 7, the via VA1 is formed so as to enclose the bonding portion BU and slit portion SLT and be in contact with the edge portion EU.

According to these features, the bottom of the slit portion SLT is covered with a tungsten film WF configuring the via VA1. Consequently, for example, moisture coming from the outside through the slit portion SLT is blocked at the bottom of the slit portion SLT. Similarly, since the tungsten film WF is formed along the sides of the slit portion SLT, the tungsten film WF configuring the via VA1 functions as a protective wall against moisture entry. According to the first embodiment, even if a slit portion SLT is formed in the pad PD, the tungsten film WF formed across the bottom and sides of the via VA1 functions as a protective wall that prevents moisture from entering inside the semiconductor chip. More specifically, the path through which moisture enters from the slit portion SLT into the semiconductor chip is blocked by the tungsten film WF configuring the via VA1, and therefore the pad structure according to the first embodiment can effectively prevent moisture entry from the slit portion SLT, which passes through the pad PD, into the semiconductor chip. Consequently, according to the features of the first embodiment, formation of the slit portion SLT filled up with the sealing member in the pad PD can relieve the stress applied to the pad PD due to wire bonding and also can prevent moisture from entering from the slit portion SLT into the semiconductor chip. Thus, the first embodiment can improve the reliability of the semiconductor device.

As described above, the via VA1 is formed so as to enclose the slit portion SLT in the first embodiment, and therefore the path toward the inside of the semiconductor chip through the slit portion SLT is configured to always be blocked by the tungsten film WF configuring the via VA1. This makes it difficult for moisture to enter inside the semiconductor chip through the slit portion SLT.

Furthermore, according to the pad structure and via structure of the first embodiment, the edge portion EU of the pad PD is formed along the sides of the via VA1 as shown in FIG. 7. In other words, in the pad structure of the first embodiment, not only the tungsten film WF that configures the via VA1, but also an aluminum film that configures the edge portion EU of the pad PD is formed between the sides of the slit portion SLT and the interlayer insulating film IL2. Thus, the tungsten film WF that configures the via VA1 and the aluminum film that configures the edge portion EU of the pad PD establish a double protection function that can prevent moisture entry especially through the sides of the slit portion SLT.

This configuration is consequently imparted from the features of the first embodiment, that is, the via VA1 is formed so as to enclose the slit portion SLT, and the edge portion EU is formed so as to partially extend from the via VA1. In other expressions, the features of the first embodiment implement a different-level structure in which the upper surface of the bonding portion BU of the pad PD is at a lower level than the upper surface of the edge portion EU of the pad PD. As a result, the pad structure of the first embodiment that implements the different-level structure can provide the sides of the slit portion SLT with the double protection function made of the tungsten film WF that configures the via VA1 and the aluminum film that configures the edge portion EU of the pad PD, thereby reliably preventing moisture from entering through the slit portion SLT.

In the first embodiment, as shown in FIG. 7, the bonding portion BU and the edge portion EU of the pad PD are electrically coupled to each other by the via VA1. Therefore, in contrast to the related art shown in FIG. 4, the first embodiment has no necessity to form a slit portion SLT that is formed along three sides of the rectangular pad PD, but is not formed along the remaining side (a side near an inner circuit area) in order to couple the bonding portion BU with the edge portion EU. That is, in the first embodiment, the slit portion SLT can be formed along all of the four sides of the rectangular pad PD. In this case, even if stress induced by wire bonding is applied to the pad PD, the sealing material embedded in the slit portion SLT after the wire bonding process can relieve the stress uniformly in all directions because the slit portion SLT completely encloses the bonding portion BU of the pad PD. This is an advantage of the first embodiment. This case also can reliably prevent moisture from entering through the slit portion SLT by adopting the via structure according to the first embodiment.

### Method for Manufacturing Semiconductor Device according to First Embodiment

The semiconductor device according to the first embodiment is configured as described above, and the manufacturing method will be described below with reference to the drawings.

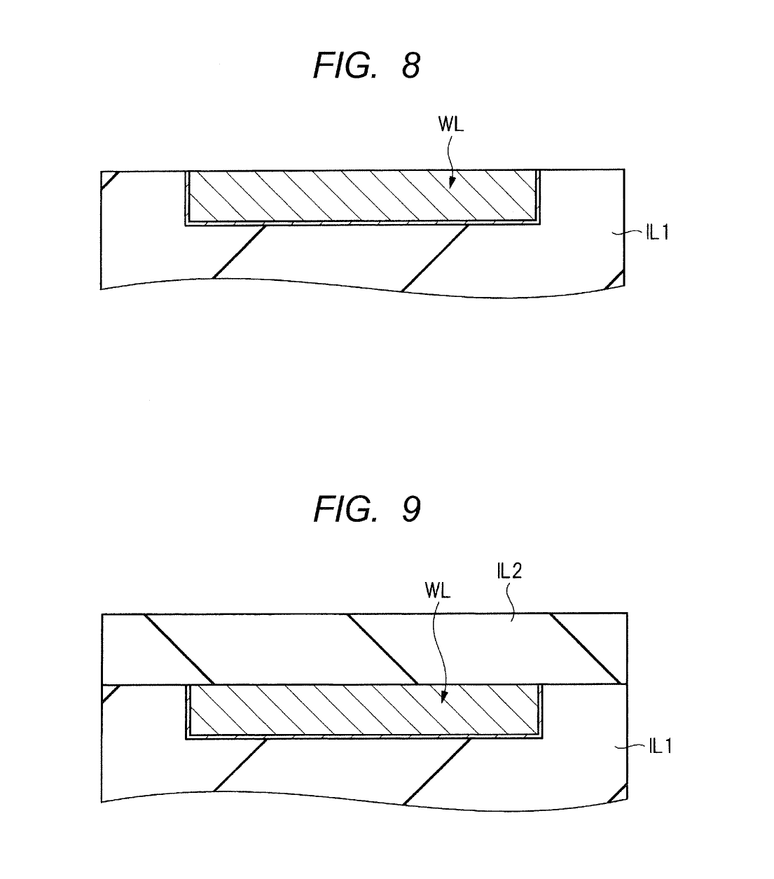

First of all, a semiconductor substrate, which is made of, for example, silicon, is prepared, and then a plurality of field-effect transistors are formed over the semiconductor substrate. Subsequently, a multilevel interconnect layer is formed over the semiconductor substrate where the field-effect transistors are formed. FIG. 8 illustrates an interlayer insulating film IL1 that is formed over the top sub-layer of the multilevel interconnect layer. This interlayer insulating film IL1 is, for example, a silicon oxide film or a film (SiOC film, etc.) having a lower dielectric constant than the silicon oxide film, and can be formed by, for example, a chemical vapor deposition (CVD) method. Then, as shown in FIG. 8, a wiring WL is formed in a trench formed in the interlayer insulating film IL1 by, for example, a damascene method. The wiring WL is made by embedding, for example, a barrier conductor film, which is a laminated film of a tantalum nitride film and a tantalum film, and a copper film containing copper as a main component.

Next, as shown in FIG. 9, an interlayer insulating film IL2 is formed over the interlayer insulating film IL1 with the wiring WL formed therein. This interlayer insulating film IL2 is, for example, a silicon oxide film or a low-dielectric-constant film, and can be formed by, for example, a CVD method.

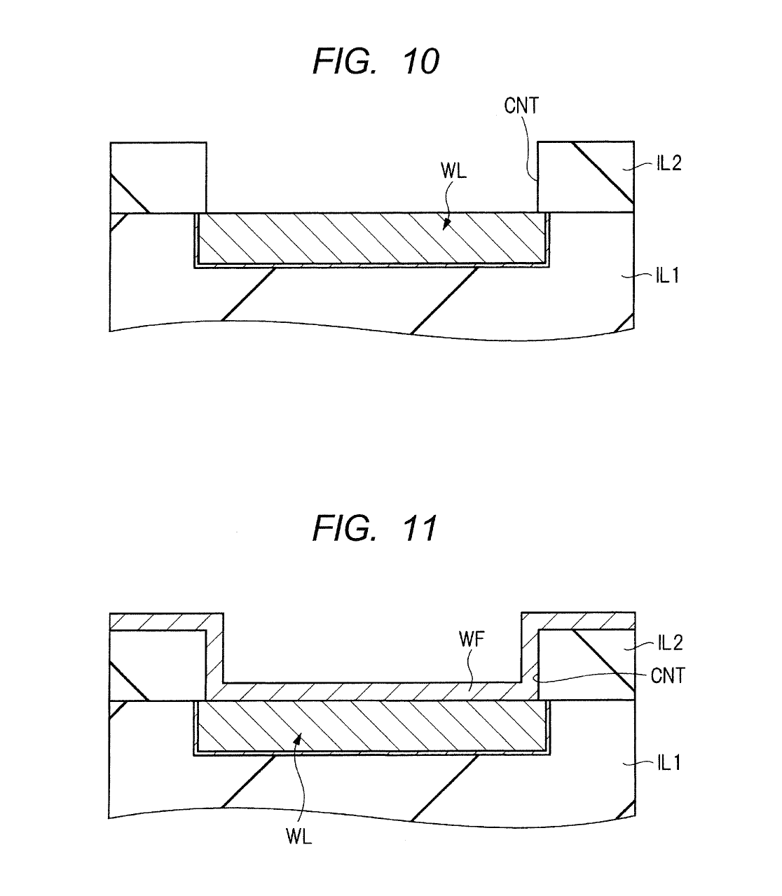

Then, as shown in FIG. 10, a coupling hole CNT is formed in the interlayer insulating film IL2 by using a photolithography technique and an etching technique. This coupling hole CNT is formed so as to pass through the interlayer insulating film IL2 and reach a surface of the wiring WL.

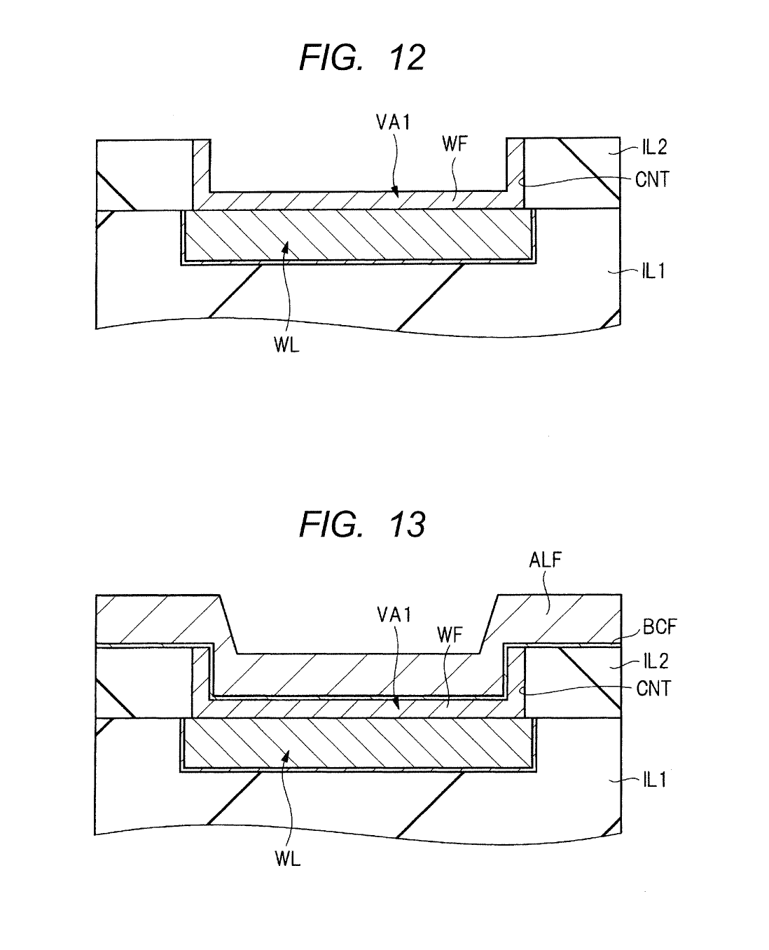

Subsequently, as shown in FIG. 11, a tungsten film WF, which contains tungsten as a main component, is formed over the interlayer insulating film IL2 including the inner walls of the coupling hole CNT by, for example, a CVD method. Then, as shown in FIG. 12, any unnecessary part of the tungsten film WF formed over the interlayer insulating film IL2 is removed by, for example, a chemical mechanical polishing (CMP) method. This removal can leave the tungsten film WF only over the inner walls of the coupling hole CNT formed in the interlayer insulating film IL2 as shown in FIG. 12, thereby forming a via VA1 comprised of the tungsten film WF in the coupling hole CNT.

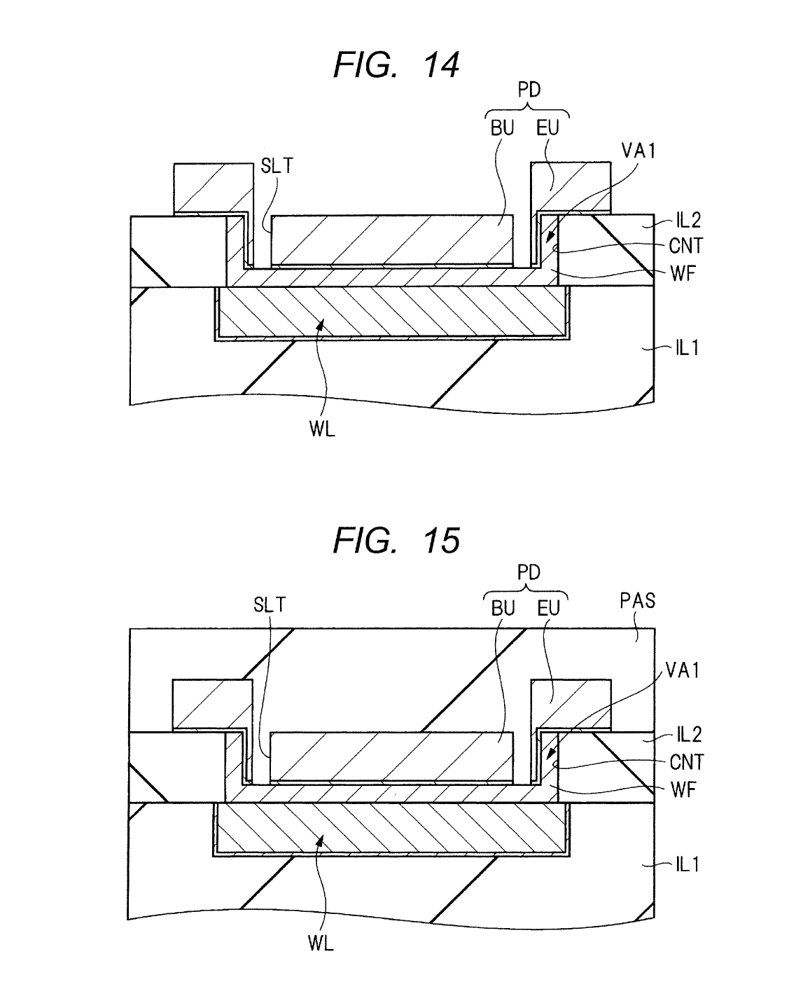

Next, as shown in FIG. 13, a barrier conductor film BCF, which is, for example, a titanium nitride film, is formed over the interlayer insulating film IL2 with the via VA1 formed therein by using, for example, a sputtering method, and then a conductor film ALF, which is an aluminum film or an aluminum alloy film (AlSi film, AlSiCu film, etc.), is formed over the barrier conductor film BCF. Subsequently, as shown in FIG. 14, the conductor film ALF and barrier conductor film BCF are patterned by using a photolithography technique and an etching technique to form a pad PD. During the patterning process, a slit portion SLT passing through the pad PD is also formed. Consequently, a pad PD with a bonding portion BU and an edge portion EU separated by the slit portion SLT can be formed.

At this point, the bonding portion BU of the pad PD is enclosed by the via VA1, and the edge portion EU of the pad PD is formed over the interlayer insulating film IL2 so as to partially extend from the via VA1. As a result, as shown in FIG. 14, the bottom of the slit portion SLT is closed with the tungsten film WF configuring the via VA1, while at the sides of the slit portion SLT, a double protection wall structure is formed with the conductor film ALF configuring part of the edge portion EU of the pad PD and the tungsten film WF configuring the via VA1. Accordingly, the first embodiment can implement the pad structure capable of preventing moisture from entering inside the semiconductor chip through the slit portion SLT, thereby improving the reliability of the semiconductor device.

Then, as shown in FIG. 15, a surface protective film PAS is formed over the interlayer insulating film IL2 where the pad PD is formed. The surface protective film PAS is, for example, a laminated film of a silicon oxide film and a silicon nitride film, and can be formed by, for example, a CVD method.

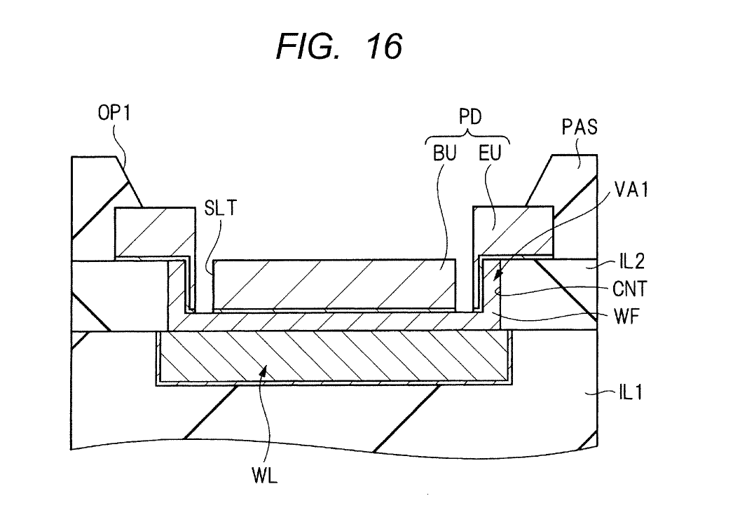

Then, as shown in FIG. 16, an opening OP1 is formed in the surface protective film PAS by using a photolithography technique and an etching technique. At this point, the bonding portion BU and part of the edge portion EU of the pad PD are exposed from the opening OP1 formed in the surface protective film PAS. An end portion of the opening OP1 is located over the edge portion EU of the pad PD. Through the above-described processes, the pad structure according to the first embodiment can be achieved.

Although it is not illustrated, after a semiconductor substrate (semiconductor wafer) is diced into a plurality of semiconductor chips, each of the semiconductor chips is mounted on a chip mount provided over a lead frame (die bonding). Then, the pad PD formed in the semiconductor chip is electrically coupled to leads provided to the lead frame with wires made of, for example, a gold wire (wire bonding). At this point, the wire bonding process applies stress on the pad PD of the first embodiment.

After wire bonding, the semiconductor chip is sealed with a sealing member, such as resin, through a molding process using a mold, for example. At this point, the slit portion SLT formed in the pad PD is filled with a sealing material configuring the sealing member. According to the first embodiment, the sealing material embedded in the slit portion SLT after the wire bonding process can resultantly relieve the stress applied on the pad PD due to wire bonding. Cutting to shape the leads can complete the manufacturing of a semiconductor device according to the first embodiment.

According to the first embodiment, as shown in FIG. 7, even if a slit portion SLT is formed in the pad PD, the tungsten film WF formed across the bottom and sides of the via VA1 functions as a protective wall that prevents moisture from entering inside the semiconductor chip. More specifically, the path through which moisture enters from the slit portion SLT into the semiconductor chip is blocked by the tungsten film WF configuring the via VA1, and therefore the pad structure according to the first embodiment can effectively prevent moisture entry into the semiconductor chip through the slit portion SLT passing through the pad PD. Consequently, according to the first embodiment, providing the slit portion SLT filled with a sealing member in the pad PD can relieve stress applied to the pad PD due to wire bonding and also can prevent moisture from entering through the slit portion SLT into the semiconductor chip. Thus, the first embodiment can improve the reliability of the semiconductor device.

### Second Embodiment

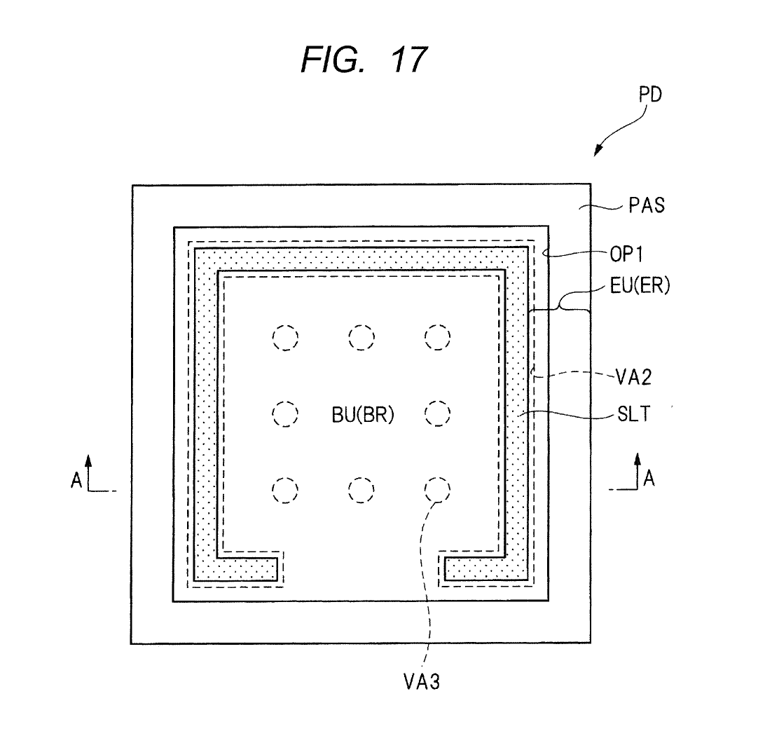

Description will be made about a pad structure and via structure according to the second embodiment. FIG. 17 is a plan view schematically showing a pad PD according to the second embodiment. The pad PD of the second embodiment shown in FIG. 17 has almost the same configuration as the pad PD of the first embodiment shown in FIG. 6, and therefore the description will be focused on their differences.

As shown in FIG. 17, the pad PD of the second embodiment also has a slit portion SLT, and a via VA2 formed in a layer below the pad PD so as to enclose the slit portion SLT. The via VA1 according to the first embodiment is formed large enough to enclose the bonding portion BU and slit portion SLT as shown in FIG. 6. On the contrary, the via VA2 according to the second embodiment is formed small enough so as to enclose the slit portion SLT, but not to enclose the bonding portion BU as shown in FIG. 17. That is, the via VA2 of the second embodiment is formed so as to enclose the slit portion SLT in plan view as with the case of the via VA1 of the first embodiment; however, the via VA2 of the second embodiment is much smaller in size than the via VA1 of the first embodiment.

Additionally, in the second embodiment, a plurality of vias VA3 are formed on the inside of the via VA2 and are coupled with the bonding portion BU as shown in FIG. 17. For example, the size of each via VA3 is smaller than the size of the via VA2 enclosing the slit portion SLT in plan view. Thus, the pad PD in the second embodiment has two kinds of vias, the via VA2 and vias VA3, coupled to the pad PD. FIG. 17 shows the plane shape of the vias VA3 coupled to the bonding portion BU as a circular via in the shape of a circle (particulate via); however, the plane shape of the vias VA3 are not limited to circles and can be in the shape of a straight line (slit shape) or in the shape of a grid pattern made by combining the plurality of vias VA3.

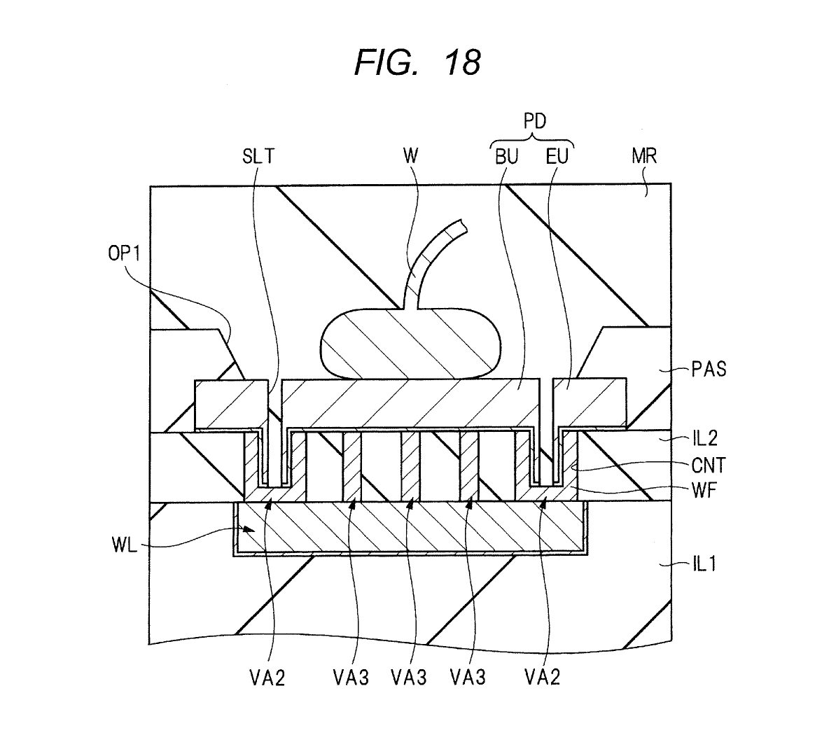

FIG. 18 is a cross-sectional view taken along line A-A in FIG. 17. As shown in FIG. 18, the via VA2 in the second embodiment is formed so as to enclose the slit portion SLT. Specifically, the via VA2 of the second embodiment encloses the slit portion SLT and is in contact with both the bonding portion BU and edge portion EU of the pad PD.

In this manner, also in the second embodiment, the bottom of the slit portion SLT is covered with a tungsten film WF configuring the via VA2. Consequently, for example, moisture coming from the outside through the slit portion SLT is blocked at the bottom of the slit portion SLT. Similarly, since the tungsten film WF exists along the sides of the slit portion SLT, the tungsten film WF configuring the via VA2 functions as a protective wall against moisture entry. According to the second embodiment, even if a slit portion SLT is formed in the pad PD, the tungsten film WF formed across the bottom and sides of the via VA2 functions as a protective wall that prevents moisture from entering inside the semiconductor chip. More specifically, the path through which moisture enters from the slit portion SLT into the semiconductor chip is blocked by the tungsten film WF configuring the via VA2, and therefore the pad structure and via structure according to the second embodiment can effectively prevent moisture entry into the semiconductor chip through the slit portion SLT passing through the pad PD.

Additionally, as shown in FIG. 18, in the second embodiment, the vias VA3 that couple the wiring WL to the bonding portion BU of the pad PD are formed on the inside of the via VA2. Even if the size of the via VA2 is made small, the coupling resistance between the pad PD and wiring WL can be decreased because the pad PD and wiring WL are coupled to each other through the via VA2 and vias VA3.

One of the features of the second embodiment resides in that the via VA2 enclosing the slit portion SLT in the second embodiment is designed to be smaller in size in comparison with the via VA1 enclosing the slit portion SLT in the first embodiment. Making the via 2 smaller as described in the second embodiment can reduce the difference in size between the via VA2 and the other vias formed in the same layer as the via VA2. Consequently, the size difference between a coupling hole CNT used to form the via VA2 and coupling holes used to form the other vias can be reduced, and therefore the difference of the etching rates that are determined in accordance with the size difference of the coupling holes can be also reduced in the coupling hole formation process. As a result, the second embodiment can prevent excessive over-etching from occurring in small-sized coupling holes.

### Third Embodiment

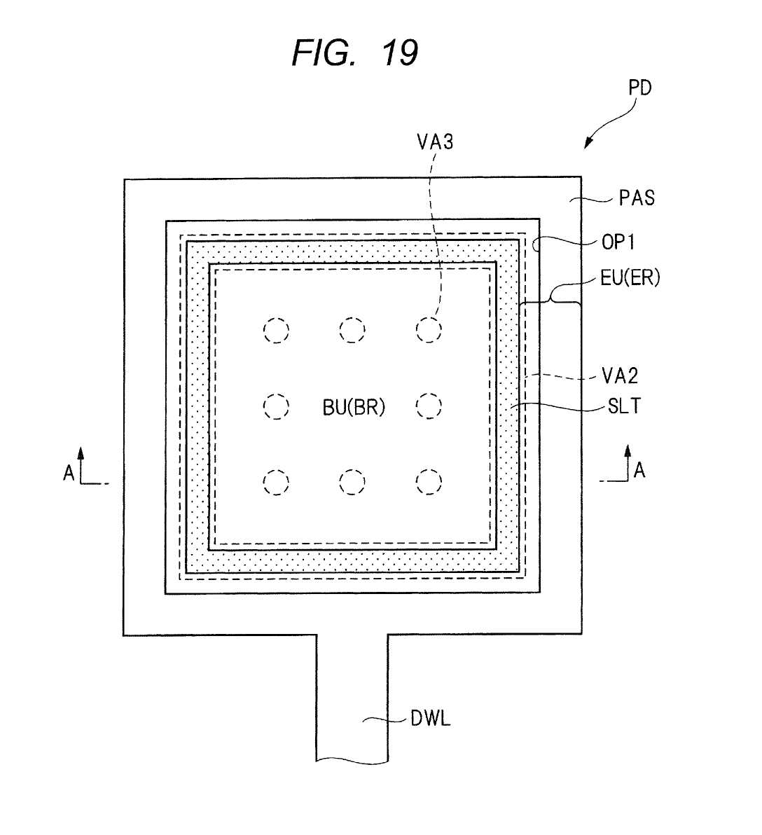

Description will be made about a pad structure and via structure according to the third embodiment. FIG. 19 is a plan view schematically showing a pad PD according to the third embodiment. The pad PD of the third embodiment shown in FIG. 19 has almost the same configuration as the pad PD of the second embodiment shown in FIG. 17, and therefore the description will be focused on their differences.

In FIG. 19, one of the features of the third embodiment resides in that the bonding portion BU of the pad PD is separated from the edge portion EU of the pad PD by a slit portion SLT in plan view. Specifically, the pad PD according to the third embodiment has a slit portion SLT that completely encloses the bonding portion BU of the pad PD as shown in FIG. 19. In other words, as shown in FIG. 19, the pad PD in the third embodiment is also rectangular and has a slit portion SLT formed along the sides thereof, but a slit-unformed region is not provided along the sides of the pad PD. In short, the pad PD according to the third embodiment is in the shape of a rectangle having four sides and the slit portion SLT is arranged along the four sides of the pad PD.

According to the third embodiment, even if stress induced by wire bonding is applied across the entire pad PD, the sealing material, which is embedded in the slit portion SLT after the wire bonding process, can relieve the stress. In the case where a slit-unformed region where a slit portion SLT is not formed is provided at a part of the pad PD, the slit-unformed region makes it difficult to relieve the stress applied on the pad PD due to wire bonding even when there is a sealing material embedded in the slit portion SLT after the wire bonding process. On the contrary, since the slit portion SLT of the third embodiment completely encloses the bonding portion BU of the pad PD as shown in FIG. 19, even if stress induced by wire bonding is applied to the pad PD, the sealing material embedded in the slit portion SLT after the wire bonding process can relieve the stress uniformly in all directions.

Once again, the slit portion SLT according to the third embodiment is arranged along the four sides of the pad PD so as to completely enclose the bonding portion BU of the pad PD. In this case, there is a concern that the bonding portion BU of the pad PD may not be electrically coupled to the edge portion EU of the pad PD. In this regard, the via structure according to the third embodiment allows the bonding portion BU of the pad PD to be electrically coupled to the edge portion EU of the pad PD, even if the slit portion SLT is formed along the four sides of the pad PD so as to completely enclose the bonding portion BU of the pad PD.

Actually, the cross-sectional view taken along line A-A in FIG. 19 is identical to that of FIG. 18 described in the second embodiment. As shown in FIG. 18, the via VA2 enclosing the slit portion SLT is coupled to the bonding portion BU of the pad PD as well as to the edge portion EU of the pad PD. Thus, the bonding portion BU of the pad PD and the edge portion EU of the pad PD are electrically coupled to each other through the via VA2. Even if the bonding portion BU is completely separated from the edge portion EU by the slit portion SLT as described in the third embodiment, the bonding portion BU of the pad PD and the edge portion EU of the pad PD are electrically coupled to each other through the via VA2 as shown in FIG. 18. According to the pad structure and via structure of the third embodiment, even if the bonding portion BU and the edge portion EU are completely separated from each other by the slit portion SLT, a leader line DWL taken out from the edge portion EU of the pad PD can be electrically coupled to a wire coupled to the bonding portion BU as shown in FIG. 19.

### Fourth Embodiment

In the first embodiment, the wiring WL formed in a layer below the pad PD is a copper wiring as an example. The fourth embodiment to be described below employs an aluminum wiring (aluminum alloy wiring) for the wiring WL formed in the layer below the pad PD, which is also an example.

### Configuration of Semiconductor Device according to Fourth Embodiment

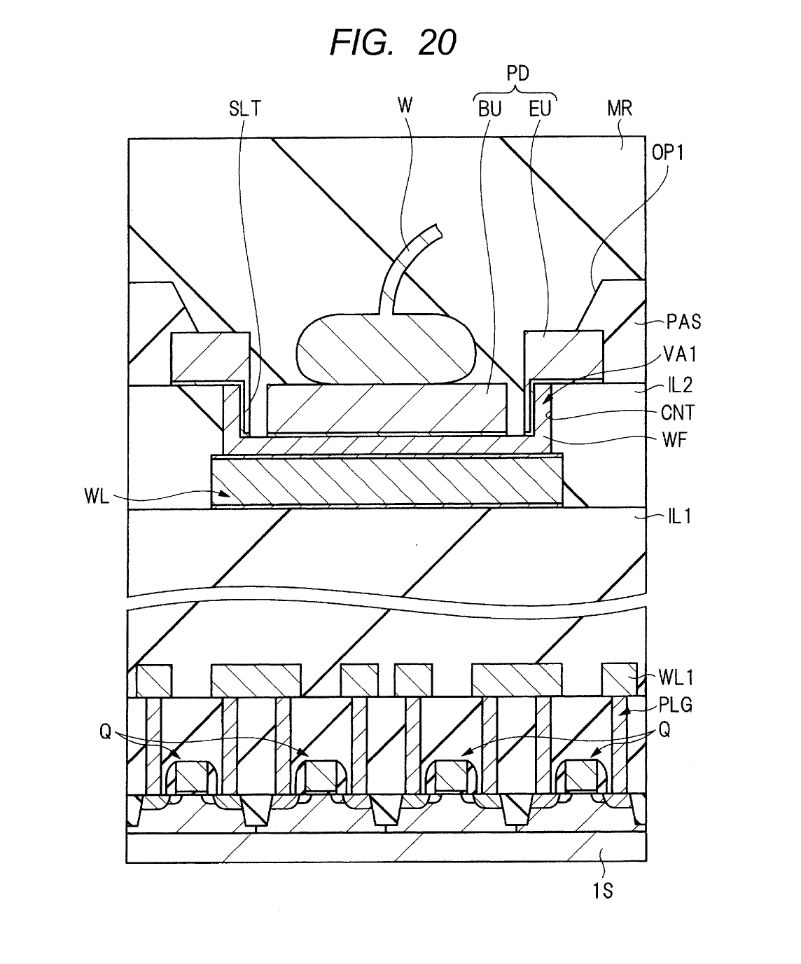

FIG. 20 is a cross-sectional view showing an exemplary configuration of a semiconductor device according to the fourth embodiment. The semiconductor device according to the fourth embodiment shown in FIG. 20 has almost the same configuration as that of the semiconductor device according to the first embodiment shown in FIG. 7. However, as shown in FIG. 20, the semiconductor device according to the fourth embodiment has an aluminum wiring (wiring WL) formed over the interlayer insulating film IL1. The aluminum wiring is, for example, an aluminum film sandwiched between barrier conductor films (laminated films of a titanium film and a titanium nitride film). In short, the difference in the semiconductor device of the fourth embodiment shown in FIG. 20 is that it has an aluminum wiring WL instead of the copper wiring WL as shown in FIG. 7. The other configuration is identical to the first embodiment.

### Method for Manufacturing Semiconductor Device according to Fourth Embodiment

The semiconductor device according to the fourth embodiment is configured as described above, and the manufacturing method will be described below with reference to the drawings.

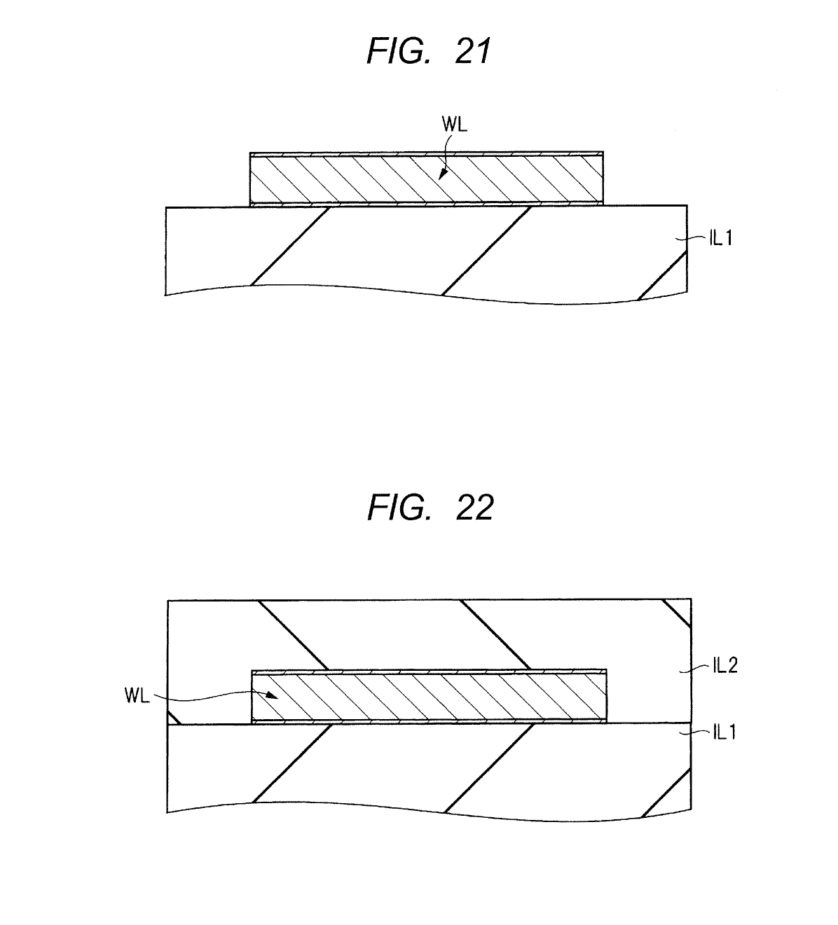

For example, as shown in FIG. 21, a wiring WL, which is a laminated film comprised of a first barrier conductor film, an aluminum film containing aluminum as a main component, and a second barrier conductor film, is formed over an interlayer insulating film IL1. Both the first and second barrier conductor films are a laminated film comprised of, for example, a titanium film and a titanium nitride film. This wiring WL can be made by, for example, forming a laminated film comprised of the first barrier conductor film, aluminum film, and second barrier conductor film over the interlayer insulating film IL1 using a sputtering method, and patterning the laminated film using a photolithography technique and an etching technique.

Next, as shown in FIG. 22, an interlayer insulating film IL2 is formed over the interlayer insulating film IL1 with the wiring WL formed. This interlayer insulating film IL2 is, for example, a silicon oxide film, and can be formed by, for example, a CVD method.

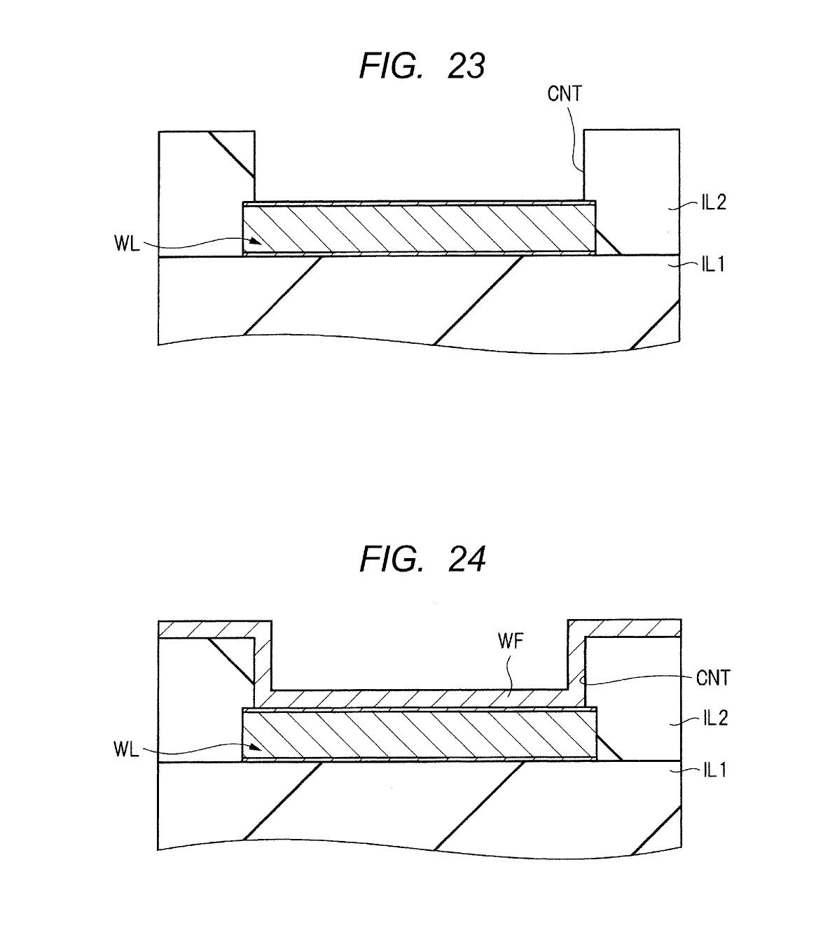

Then, as shown in FIG. 23, a coupling hole CNT is formed in the interlayer insulating film IL2 by using a photolithography technique and an etching technique. This coupling hole CNT is formed so as to pass through the interlayer insulating film IL2 and reach a surface of the wiring WL.

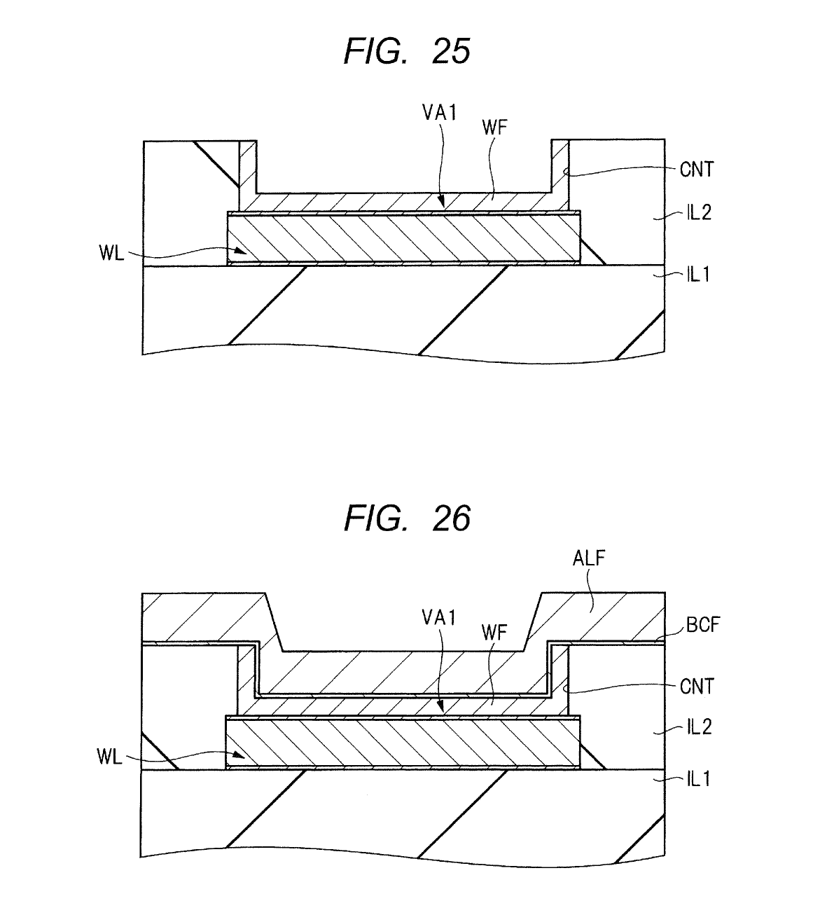

Subsequently, as shown in FIG. 24, a tungsten film WF, which contains tungsten as a main component, is formed over the interlayer insulating film IL2 including the inner walls of the coupling hole CNT by, for example, a CVD method. Then, as shown in FIG. 25, any unnecessary part of the tungsten film WF formed over the interlayer insulating film IL2 is removed by, for example, a chemical mechanical polishing method. These processes can leave the tungsten film WF only along the inner walls of the coupling hole CNT formed in the interlayer insulating film IL2 as shown in FIG. 25, thereby forming a via VA1 comprised of the tungsten film WF in the coupling hole CNT.

Next, as shown in FIG. 26, a barrier conductor film BCF, which is, for example, a titanium nitride film, is formed over the interlayer insulating film IL2 with the via VA1 formed therein by using, for example, a sputtering method, and then a conductor film ALF, which is an aluminum film or an aluminum alloy film (AlSi film, AlSiCu film, etc.), is formed over the barrier conductor film BCF. Subsequently, as shown in FIG. 27, the conductor film ALF and barrier conductor film BCF are patterned by using a photolithography technique and an etching technique to form a pad PD. During the patterning process, a slit portion SLT passing through the pad PD is also formed. Consequently, a pad PD with a bonding portion BU and an edge portion EU separated from each other by the slit portion SLT can be formed.

At this point, the bonding portion BU of the pad PD is enclosed by the via VA1, while the edge portion EU of the pad PD is formed over the interlayer insulating film IL2 so as to partially extend from the via VA1. As a result, as shown in FIG. 27, the bottom of the slit portion SLT is closed with the tungsten film WF configuring the via VA1, while at the sides of the slit portion SLT, a double protection wall structure is formed with the conductor film ALF configuring part of the edge portion EU of the pad PD and the tungsten film WF configuring the via VA1. Accordingly, the fourth embodiment can implement the pad structure capable of preventing moisture from entering inside the semiconductor chip through the slit portion SLT, thereby improving the reliability of the semiconductor device.

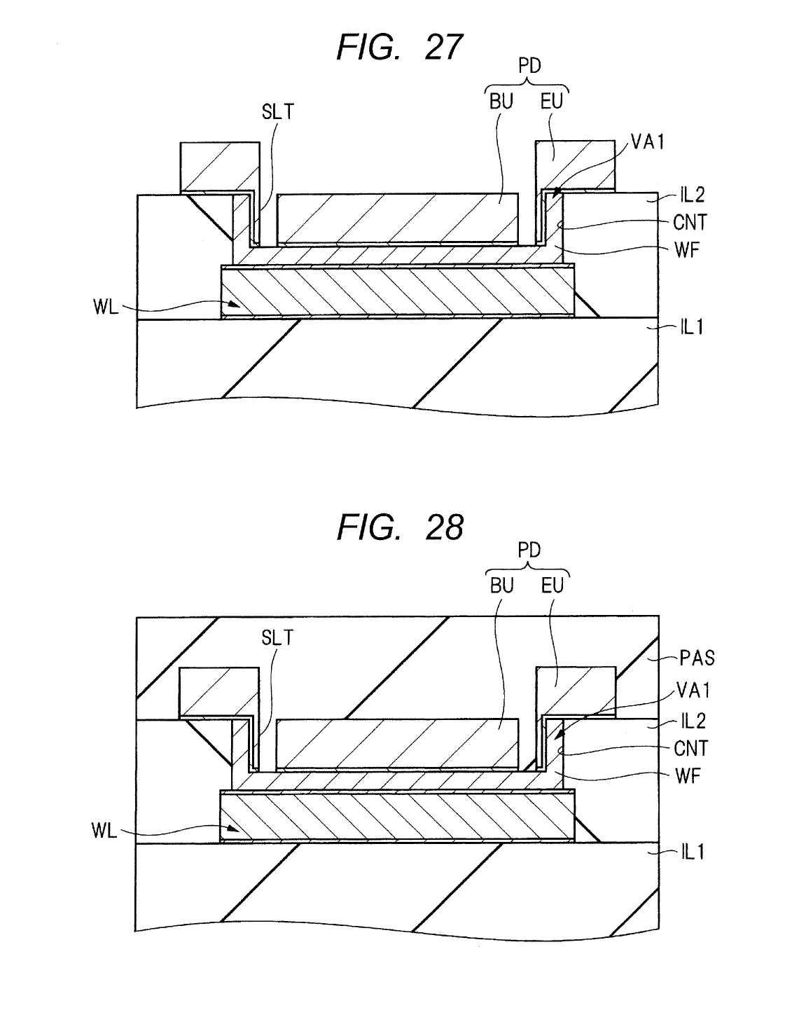

Then, as shown in FIG. 28, a surface protective film PAS is formed over the interlayer insulating film IL2 where the pad PD is formed. The surface protective film PAS is, for example, a laminated film of a silicon oxide film and a silicon nitride film, and can be formed by, for example, a CVD method.

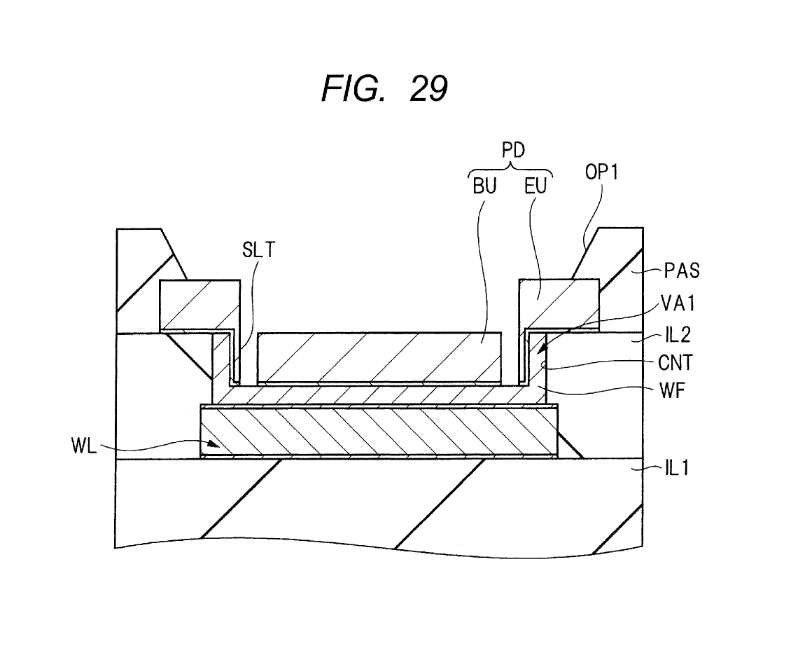

Then, as shown in FIG. 29, an opening OP1 is formed in the surface protective film PAS by using a photolithography technique and an etching technique. At this point, the bonding portion BU and part of the edge portion EU of the pad PD are exposed from the opening OP1 formed in the surface protective film PAS. An end portion of the opening OP1 is located over the edge portion EU of the pad PD. Through the above-described processes, the pad structure according to the fourth embodiment can be achieved. Subsequently, the same processes as the first embodiment are performed to manufacture a semiconductor device according to the fourth embodiment.

### Fifth Embodiment

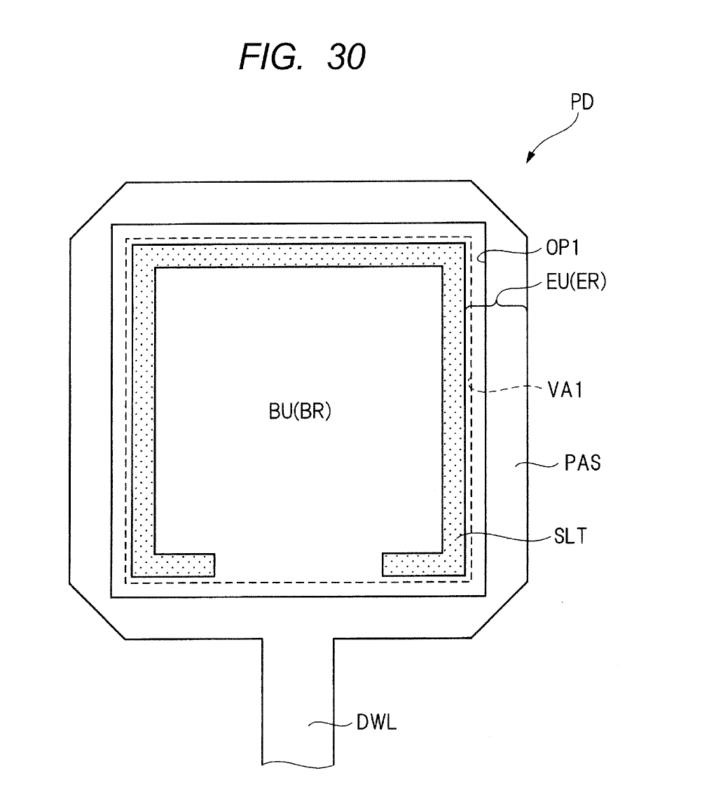

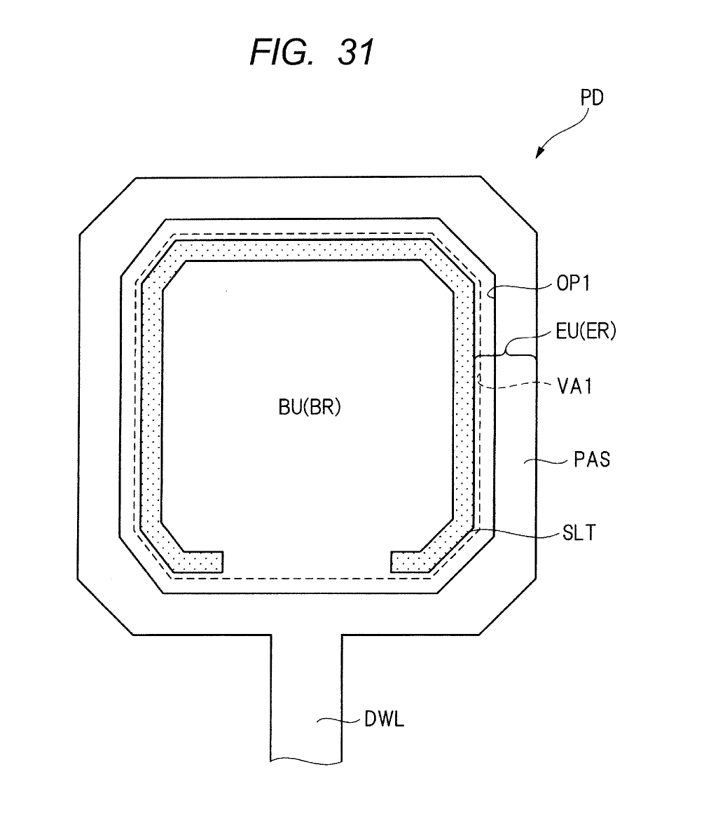

FIGS. 30 and 31 are plan views respectively showing a plane shape of a pad PD according to the fifth embodiment. As shown in FIGS. 30 and 31, the pad PD according to the fifth embodiment has chamfers at the four corners. The chamfers shape the pad PD of the fifth embodiment into an octagon, but the technical idea of the first embodiment can be applied to such a polygonal pad PD. The slit portion SLT to be formed in the polygonal pad PD can be shaped as shown in FIG. 30 or FIG. 31, for example. However, the slit portion SLT formed in the pad PD is not limited to the shape shown in FIG. 30 and can be shaped so as to completely enclose a rectangular bonding portion BU without a slit-unformed region. Similarly, the slit portion SLT formed in the pad PD is not limited to the shape shown in FIG. 31 and can be shaped so as to completely enclose an octagonal bonding portion BU without a slit-unformed region.

While the invention made by the present inventors has been described with reference to the foregoing embodiments, it goes without saying that the present invention is not limited to the embodiments and that various modifications can be made without departing from the gist of the invention.

What is claimed is:

1. A semiconductor device comprising:
a semiconductor substrate;
a wiring that is formed above the semiconductor substrate;
a first via that is formed over the wiring and electrically coupled to the wiring;
a pad that is formed over the first via and electrically coupled to the first via;
a surface protective film that covers the pad; and
an opening that is formed in the surface protective film and exposes a part of a surface of the pad,
wherein the pad includes:
a slit portion that passes through the pad;
a bonding portion that is positioned inside the slit portion in plan view; and
an edge portion that is positioned outside the slit portion in plan view, and
wherein, in plan view, the first via encloses the slit portion and is in contact with the bonding portion of the pad and the edge portion of the pad.

2. The semiconductor device according to claim 1,
wherein, in plan view, the first via encloses the bonding portion and the slit portion of the pad and is in contact with the edge portion of the pad.

3. The semiconductor device according to claim 1,
wherein, a surface of the first via is exposed from the bottom of the slit portion.

4. The semiconductor device according to claim 1,
wherein, the slit portion is filled up with a sealing member for the semiconductor device.

5. The semiconductor device according to claim 1,
wherein, the upper surface of the bonding portion of the pad is at a lower level than the upper surface of the edge portion of the pad.

6. The semiconductor device according to claim 1,
wherein, in plan view, the opening encloses the bonding portion and the slit portion of the pad.

7. The semiconductor device according to claim 1, further comprising:
a second via that is coupled to the wiring and the pad.

8. The semiconductor device according to claim 7,
wherein, the second via is coupled to the bonding portion of the pad.

9. The semiconductor device according to claim 8,
wherein, in plan view, the second via is positioned within the bonding portion of the pad.

10. The semiconductor device according to claim 7,
wherein, a plurality of the second vias are present.

11. The semiconductor device according to claim 7,
wherein, the second via is smaller in size than the first via.

12. The semiconductor device according to claim 1,
wherein, in plan view, the bonding portion of the pad is separated from the edge portion of the pad by the slit portion.

13. The semiconductor device according to claim 12,
wherein, the slit portion encloses the bonding portion of the pad.

14. The semiconductor device according to claim 13,
wherein, the pad is in the shape of a rectangle with four sides, and
wherein, the slit portion is arranged along the four sides of the pad.

15. The semiconductor device according to claim 12,
wherein, the bonding portion of the pad is electrically coupled to the edge portion of the pad through the first via.
